(19) United States
(12) Patent Application Publication
(10) Pub. No.: US 2025/0194054 A1
(43) Pub. Date: Jun. 12, 2025

(54) HEAT SINK, ELECTRONIC DEVICE, AND CIRCUIT BOARD

(71) Applicant: CANAAN CREATIVE CO., LTD., BEIJING (CN)

(72) Inventors: Huan YANG, BEIJING (CN); Jiakun MA, BEIJING (CN); Nangeng ZHANG, BEIJING (CN)

(21) Appl. No.: 18/846,191

(22) PCT Filed: Apr. 3, 2023
(86) PCT No.: PCT/CN2023/086015

§ 371 Date: Sep. 11, 2024

(30) Foreign Application Priority Data
Apr. 2, 2022 (CN) 202210351427.0
Apr. 2, 2022 (CN) 202220763671.3
May 7, 2022 (CN) 202210494701.X
May 7, 2022 (CN) 202221082980.0

(51) Int. Cl. H05K 7/20; H05K 1/02

(52) U.S. Cl. CPC H05K 7/20409; H05K 1/0203; H05K 7/20509; H05K 2201/066

(57) ABSTRACT

A heat dissipation apparatus, an electronic device, and a circuit board are provided. The heat dissipation apparatus includes: a base; and multiple heat sinks, the multiple heat sinks being arranged on the base at intervals in a first direction, two adjacent heat sinks and the base jointly defining a heat dissipation channel that extends in a second direction perpendicular to the first direction. The technical solution of the embodiments of the present application can effectively satisfy the heat dissipation requirements of the circuit board, such that heat generated by a heating apparatus during the operation process can be discharged in time, thereby effectively prolonging the service life of the heating apparatus while ensuring the normal operation of the heating apparatus.

### CROSS REFERENCE TO RELATED APPLICATIONS

This application is a U.S. national stage application under 35 U.S.C. § 371 of International Application No. PCT/CN2023/086015, filed internationally on Apr. 3, 2023, which claims priority to Chinese Patent Application No. 202210351427.0, filed with the China National Intellectual Property Administration on Apr. 2, 2022 and titled “HEAT SINK AND ELECTRONIC DEVICE”, which are incorporated herein by reference in their entirety.

International Application No. PCT/CN2023/086015 also claims priority to Chinese Patent Application No. 202220763671.3, filed with the China National Intellectual Property Administration on Apr. 2, 2022 and titled “HEAT SINK AND ELECTRONIC DEVICE”, which is incorporated herein by reference in its entirety.

International Application No. PCT/CN2023/086015 also claims priority to Chinese Patent Application No. 202210494701.X, filed with the China National Intellectual Property Administration on May 7, 2022 and titled “HEAT SINK, ELECTRONIC DEVICE, AND CIRCUIT BOARD”, which is incorporated herein by reference in its entirety.

International Application No. PCT/CN2023/086015 also claims priority to Chinese Patent Application No. 202221082980.0, filed with the China National Intellectual Property Administration on May 7, 2022 and titled “HEAT SINK, ELECTRONIC DEVICE, AND CIRCUIT BOARD”, which is incorporated herein by reference in its entirety.

### TECHNICAL FIELD

The present application relates to the field of heat dissipation technology, and, in particular, to a heat sink, an electronic device, and a circuit board.

### BACKGROUND

In the related technology, a plurality of electronic components on a circuit board generate heat in an operation process. In a case where the heat cannot be discharged in time, the normal operation of the electronic components is affected, and the service life of the electronic components is greatly reduced.

### SUMMARY

Embodiments of the present application provide a heat sink, an electronic device, and a circuit board to solve or alleviate one or more technical problems in the existing technology.

As a first aspect of the embodiments of the present application, an embodiment of the present application provides a heat sink, including: a base; and a plurality of heat dissipation fins disposed on the base at intervals along a first direction, wherein two of the heat dissipation fins adjacent to each other and the base jointly define a heat dissipation channel extending along a second direction perpendicular to the first direction.

In an implementation, along the first direction or the second direction, the heat dissipation capacity of at least part of the heat dissipation fins in at least one end region is less than the heat dissipation capacity of at least part of the heat dissipation fins located in a middle region.

In an implementation, along the first direction or the second direction, the overall rib face efficiency of at least part of the heat dissipation fins in at least one end region is less than the overall rib face efficiency of at least part of the heat dissipation fins located in a middle region.

In an implementation, along the first direction or the second direction, the height of at least part of the heat dissipation fins in at least one end region is less than the height of at least part of the heat dissipation fins located in a middle region.

In an implementation, along the first direction or the second direction, the width of at least part of the heat dissipation channels in at least one end region is greater than the width of at least part of the heat dissipation channels located in a middle region.

In an implementation, along the first direction or the second direction, the surface area of at least part of the heat dissipation fins in at least one end region is less than the surface area of at least part of the heat dissipation fins located in a middle region.

In an implementation, along the first direction or the second direction, the thermal conductivity of at least part of the heat dissipation fins in at least one end region is less than the thermal conductivity of at least part of the heat dissipation fins located in a middle region.

In an implementation, along the first direction or the second direction, the height of at least one end of at least one of the heat dissipation fins is less than the height of a middle portion of the heat dissipation fin.

As a second aspect of the embodiments of the present application. an embodiment of the present application provides an electronic device, including: a circuit board having a first side provided with a plurality of heat generation components; and a plurality of heat sinks according to any one implementation of the above aspect of the present application, wherein the heat sinks are disposed on the first side or a second side of the circuit board.

In an implementation, the heat sinks include a first heat sink disposed on the first side, and a base of the first heat sink is at least partially in contact with the corresponding heat generation component(s).

In an implementation, an insulating layer is disposed on the first heat sink, and the insulating layer at least partially covers a surface of the first heat sink.

In an implementation, at least one heat conducting member is disposed between the circuit board and the heat sinks.

In an implementation, the plurality of heat generation components are disposed at intervals along the first direction to define a plurality of heat dissipation gaps, the circuit board is adapted to be placed in heat dissipation channels, and, along the first direction or the second direction, the dimension of at least part of the heat dissipation gaps in at least one end region is less than the dimension of at least part of the heat dissipation gaps located in a middle region.

In an implementation, the electronic device further includes: a shell, wherein an accommodating cavity is defined in the shell, the circuit board and the heat sinks are both located in the accommodating cavity, a guide strip is provided on one of the shell and the heat sinks, a guide slot is formed on the other of the shell and the heat sinks, and the guide strip is movably fitted in the guide slot.

As a third aspect of the embodiments of the present application, an embodiment of the present application provides a circuit board, including: a substrate; and a plurality of heat generation components disposed on a first side of the substrate, wherein the plurality of heat generation components is disposed at intervals along a first direction to define a plurality of heat dissipation gaps, the circuit board is adapted to be placed in heat dissipation channels, and the first direction is a direction perpendicular to an extending direction of the heat dissipation channels.

In an implementation, along the first direction or the extending direction of the heat dissipation channel, the dimension of at least part of the heat dissipation gaps in at least one end region is less than the dimension of at least part of the heat dissipation gaps located in a middle region.

The embodiments of the present application adopt the above technical solutions to effectively satisfy the heat dissipation requirements of the circuit board, such that heat generated by the heat generation components in an operation process can be discharged in time, thereby effectively prolonging the service life of the heat generation components while ensuring the normal operation of the heat generation components.

The above summary is only for the purpose of the specification, and is not intended to make limitations in any way. In addition to the aspects, implementations, and features described above, further aspects, implementations, and features of the present application will be easily understood by referring to the drawings and the following detailed description.

### BRIEF DESCRIPTION OF THE DRAWINGS

In the drawings, unless otherwise specified, the same reference numerals throughout the plurality of drawings represent the same or similar components or elements. These drawings are not necessarily drawn to scale. It should be understood that these drawings only depict some implementations disclosed in the present application and should not be regarded as limitations on the scope of the present application.

FIG. 1a, FIG. 1b, FIG. 1c, and FIG. 1d show schematic structural views of a heat sink according to an embodiment of the present application;

FIG. 2 shows a schematic structural view of a heat sink according to another embodiment of the present application;

FIG. 3 shows a schematic view of a locally three-dimensional structure of an electronic device according to an embodiment of the present application;

FIG. 4 shows an exploded view of the electronic device shown in FIG. 3;

FIG. 5 shows a front view of the electronic device shown in FIG. 3;

FIG. 6 shows a top view of the electronic device shown in FIG. 3;

FIG. 7 shows a left view of the electronic device shown in FIG. 3;

FIG. 8 shows a schematic structural view of a circuit board according to an embodiment of the present application; and

FIG. 9 shows a schematic structural view of a circuit board according to another embodiment of the present application.

### REFERENCE NUMERALS

100: heat sink;
110: base;
120: heat dissipation fin;
130: heat dissipation channel;
140: guide slot;
200: electronic device;
210: circuit board;
211: heat generation component;
212: heat dissipation gap.

### DETAILED DESCRIPTION

Only some exemplary embodiments are briefly described below. Just as those skilled in the art may appreciate, the described embodiments may be modified in various ways without departing from the spirit or scope of the present application. Therefore, the drawings and description are considered to be exemplary in nature, not limitative.

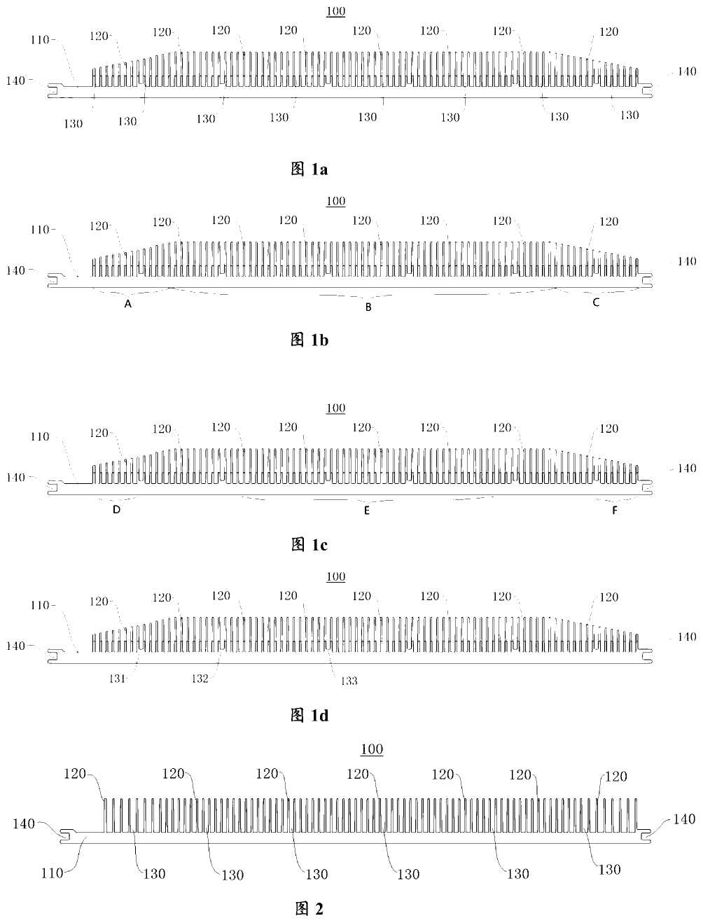

FIG. 1a shows a schematic structural view of a heat sink 100 according to an embodiment of the first aspect of the present application. The heat sink 100 can perform heat dissipation for a circuit board 210. In the following description of the present application, an explanation is made by taking an example in which the heat sink 100 is used to perform heat dissipation for the circuit board 210. Certainly, those skilled in the art can understand that the heat sink 100 can also perform heat dissipation for other heat generation structures, which is not limited to the circuit board 210.

As shown in FIG. 1a, this heat sink 100 includes a base 110 and a plurality of heat dissipation fins 120. In the description of the present application, “plurality” means two or more.

Specifically, the plurality of heat dissipation fins 120 are disposed on the base 110 at intervals along a first direction, and two of heat dissipation fins 120 adjacent to each other and the base 110 jointly define a heat dissipation channel 130 extending along a second direction perpendicular to the first direction.

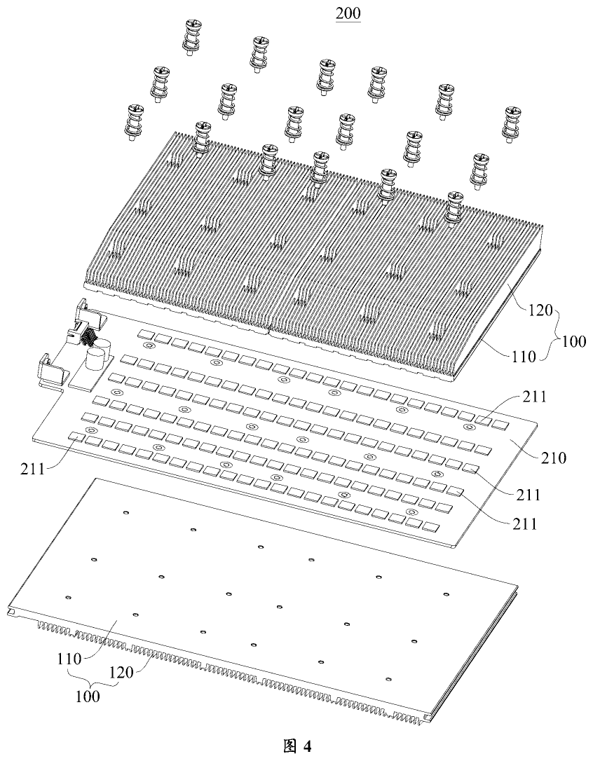

Exemplarily, in conjunction with FIG. 1a and FIG. 4, heat generated by heat generation components 211 on the circuit board 210 can be conducted to the base 110 and the plurality of heat dissipation fins 120. The heat sink 100 can be an air-cooled heat sink. In the following description of the present application, an explanation is made by taking as an example in which the heat sink 100 is an air-cooled heat sink. Certainly, those skilled in the art can understand that the heat sink 100 can also be heat sinks of other types, such as a liquid-cooled heat sink, which is not limited in the present application.

When air blows from an air inlet side of the heat dissipation channel 130 to an air blowing side, heat on the base 110 and the plurality of heat dissipation fins 120 can be taken away, such that the temperature of the circuit board 210 can be effectively reduced, and the normal operation of the heat generation components 211 can be achieved. The first direction can be a length direction of the circuit board 210, and the second direction can be a width direction of the circuit board 210. In a case where the circuit board 210 is applied to an electronic device 200 such as a mining machine, the length direction of the circuit board 210 can be perpendicular to the ground, and the width direction of the circuit board 210 can be parallel to the ground.

According to the heat sink 100 of the embodiment of the present application, the heat dissipation requirements of the circuit board 210 can be effectively satisfied, such that the heat generated by the heat generation components 211 in an operation process can be discharged in time, thereby effectively prolonging the service life of the heat generation components 211 while ensuring the normal operation of the heat generation components 211.

In an implementation, along the first direction or the second direction, the heat dissipation capacity of the heat dissipation fins 120 located in two end regions of the base 110 is less than the heat dissipation capacity of the heat dissipation fins 120 located in a middle region of the base 110.

In one embodiment, the “heat dissipation capacity” of heat dissipation fins in a certain region can be understood as the capacity of the heat dissipation fins in this region to dissipate heat. Specifically, the “heat dissipation capacity” of heat dissipation fins in a certain region can be understood as an overall heat transfer coefficient k of the heat dissipation fins in this region under certain external conditions (e.g., in a case where the physical properties, flow rate and the like of air or other heat dissipation fluids remain constant). The overall heat transfer coefficient k can be used to characterize a value of a heat flow when a temperature difference between cold and hot media is 1° C. and a heat transfer area is 1 m², which serves as a scale for the intensity of a heat transfer process (in the present application, corresponding to a heat dissipation process). The physical meaning of the overall heat transfer coefficient k is clear and unambiguous for those of ordinary skill in the art, which can be specifically referred to in the relevant records in Heat Transfer (edited by YANG Shiming and TAO Wenquan, 4th Edition, August 2006, Higher Education Press).

In another embodiment, the “heat dissipation capacity” of heat dissipation fins in a certain region can be understood as the heat dissipation performance of the heat dissipation fins in this region, that is, the performance of diffusion of heat of a system to the outside, which is an index for characterizing the heat dissipation quality of the system. The heat dissipation performance can be a ratio between the power of a heat source and a temperature difference between two ends of an object, which is reciprocal to thermal resistance.

Parameters that affect the heat dissipation capacity of a heat dissipation fin can include a shape of the heat dissipation fin, a length of the heat dissipation fin, a height of the heat dissipation fin, a thickness of the heat dissipation fin, a thermal conductivity of the heat dissipation fin, a surface area of the heat dissipation fin, and the like. In a case of comparing heat dissipation fins in terms of heat dissipation capacity, the same parameter of the heat dissipation fins may be compared, or different parameters of the heat dissipation fins may be compared, or a comparison may also be performed taking a plurality of parameters into account.

Exemplarily, in a case where external conditions and other parameters are the same, the larger the surface area of a heat dissipation fin, the greater the heat dissipation capacity; or, in the case where the external conditions and other parameters are the same, the higher the thermal conductivity of the heat dissipation fin, the greater the heat dissipation capacity.

The “middle region” and “end region” (including one end region or two end regions) should be understood in broad sense in the present application, that is, the “middle region” and “end region” are relative concepts with a center of the heat sink (or a center of the base) as a reference thereof. No limitation is made in this embodiment on a range or size of the one end region, the two end regions, or the middle region.

In one example, as shown in FIG. 1b, for the heat sink 100, the middle region can be region B, and the end regions can be region A and/or region C.

In another example, the middle region can be a region close to the center of the heat sink, the end regions can be regions away from the center of the heat sink, and there can be overlapping parts between the range of the middle region and the ranges of the end regions. That is to say, in FIG. 1b, there can be an overlapping region between the region A as an end region and the region B as the middle region, and there can also be an overlapping region between the region C as an end region and the region B as the middle region.

In yet another example, the middle region can be a region close to the center of the heat sink, and the end regions can be regions away from the center of the heat sink compared to the middle region, and there are no overlapping parts between the middle region and the end regions. For example, as shown in FIG. 1c, a region D as an end region does not overlap with a region E as the middle region, and a region F as an end region does not overlap with the region E as the middle region.

In still another example, as shown in FIG. 1d, the heat sink 100 includes protrusions 131, 132, and 133 protruding from the base 110, wherein a region to the left of the protrusion 131 can serve as one end region, and a region between the protrusion 132 and the protrusion 133 can serve as one middle region.

Exemplarily, a distance between the two end regions in the length direction of the circuit board 210 and the outside is short, and heat exchange can be performed with the outside to a certain extent. Therefore, the temperature of the two end regions is relatively low, and the heat dissipation requirement is relatively low. A distance between the middle region in the length direction of the circuit board 210 and the outside is long, and heat cannot be effectively dissipated, such that the temperature is relatively high, and the heat dissipation requirement is relatively high.

By enabling the heat dissipation capacity of the heat dissipation fins 120 located in the two end regions to be less than the heat dissipation capacity of the heat dissipation fins 120 located in the middle region, the heat dissipation capacity of the heat dissipation fins 120 in the middle region is relatively high, such that air can effectively take away heat generated by the heat generation components 211 in a middle portion of the circuit board 210 in a process of flowing through the heat dissipation channels 130; and the heat dissipation capacity of the heat dissipation fins 120 in the two end regions is relatively low, which can reduce the cost of the heat sink 100 while ensuring the normal operation of heat generation components 211 at both ends of the circuit board 210.

According to the heat sink 100 of the embodiment of the present application, in which the heat dissipation capacity of the heat dissipation fins 120 located in the two end regions with a relatively low heat dissipation requirement is relatively small, and the heat dissipation capacity of the heat dissipation fins 120 located in the middle region with a relatively high heat dissipation requirement is relatively large, heat dissipation can be performed according to heat dissipation requirements of different regions on the circuit board 210, such that temperatures of a plurality of heat generation components 211 on the circuit board 210 are more uniform, the service life of the plurality of heat generation components 211 is prolonged, and the cost of the entire heat sink 100 can be reduced.

In an implementation, along the first direction or the second direction, the heat dissipation capacity of at least part of the heat dissipation fins 120 in at least one end region is less than the heat dissipation capacity of at least part of the heat dissipation fins 120 located in a middle region.

Exemplarily, the heat dissipation capacity of a part of the heat dissipation fins 120 in one of the end regions may be less than the heat dissipation capacity of a part of the heat dissipation fins 120 located in the middle region, and there can exist a heat dissipation fin 120 in the above one of the end regions with a heat dissipation capacity greater than or equal to the heat dissipation capacity of the heat dissipation fins 120 located in the middle region. Alternatively, the heat dissipation capacity of all the heat dissipation fins 120 in the one of the end regions may be less than the heat dissipation capacity of the heat dissipation fins 120 located in the middle region. Still alternatively, it is also possible that the heat dissipation capacity of a part of the heat dissipation fins 120 in either end region is less than the heat dissipation capacity of the part of the heat dissipation fins 120 located in the middle region, and there can exist a heat dissipation fin 120 in either end region with a heat dissipation capacity greater than or equal to the heat dissipation capacity of the heat dissipation fins 120 located in the middle region. Yet alternatively, the heat dissipation capacity of all the heat dissipation fins 120 in both end regions may be less than the heat dissipation capacity of the heat dissipation fins 120 located in the middle region.

Exemplarily, the heat dissipation capacity of at least part of the heat dissipation fins 120 may gradually decrease from the middle to the two ends. An overall trend of the heat dissipation capacity of the plurality of heat dissipation fins 120 can gradually decrease from the middle to the two ends. At this time, the heat dissipation capacity of all the heat dissipation fins 120 may gradually decrease from the middle to the two ends. Alternatively, the heat dissipation capacity of a part of the plurality of heat dissipation fins 120 gradually decreases from the middle to the two ends, and the heat dissipation capacity of the other part of the plurality of heat dissipation fins 120 does not gradually decrease from the middle to the two ends, for example, the heat dissipation capacity of the above other part of the heat dissipation fins 120 may not gradually decrease from the middle to the two ends due to assembly requirements, such as a requirement to avoid certain components.

Thus, in a case where the heat sink 100 is applied to the electronic device 200, a distance between the plurality of heat dissipation fins 120 and the outside gradually decreases from the middle to the two ends along the first direction, and the heat dissipation requirement gradually decreases from the middle to the two ends. By enabling the heat dissipation capacity of at least part of the heat dissipation fins 120 to gradually decrease from the middle to the two ends, the heat dissipation capacity of at least the part of the heat dissipation fins 120 is positively correlated with a heat dissipation requirement of the corresponding heat generation components 211, thereby further enhancing the temperature uniformity of the plurality of heat generation components 211 on the circuit board 210, while ensuring that the heat sink 100 has a better heat dissipation effect.

In an implementation, the plurality of heat dissipation fins 120 can be divided into a plurality of first heat dissipation groups, wherein at least one first heat dissipation group includes a plurality of heat dissipation fins 120 equal in heat dissipation capacity, and the heat dissipation capacity of the heat dissipation fins 120 of the plurality of first heat dissipation groups gradually decreases from the middle to the two ends along the first direction.

For example, in a case where the plurality of heat dissipation fins 120 are divided into three first heat dissipation groups, the three first heat dissipation groups are a first heat dissipation group I, a first heat dissipation group II and a first heat dissipation group III arranged in sequence along the first direction, respectively. The first heat dissipation group I and the first heat dissipation group II may include a plurality of heat dissipation fins 120 equal in heat dissipation capacity, respectively. At this time, along the first direction, the heat dissipation capacity of the heat dissipation fins 120 in the first heat dissipation group II is greater than the heat dissipation capacity of the heat dissipation fins 120 in the first heat dissipation group I, and the heat dissipation capacity of the heat dissipation fins 120 in the first heat dissipation group II is greater than the heat dissipation capacity of heat dissipation fins 120 in the first heat dissipation group III. The heat dissipation capacity of a plurality of heat dissipation fins 120 in the first heat dissipation group III can be equal, can progressively increase or decrease from the middle to the two ends, can progressively increase or decrease in sequence along the first direction, or without any rule, as long as the heat dissipation capacity of the heat dissipation fins 120 in the first heat dissipation group III is less than the heat dissipation capacity of the heat dissipation fins 120 in the first heat dissipation group II.

Thus, with the above arrangement, the plurality of first heat dissipation groups can perform heat dissipation according to heat dissipation requirements of different regions on the circuit board 210, and since the plurality of heat dissipation fins 120 in the at least one first heat dissipation group are equal in heat dissipation capacity, the versatility of the plurality of heat dissipation fins 120 in the above at least one first heat dissipation group can be improved, thereby reducing the machining difficulty of the heat sink 100 and improving the production efficiency of the heat sink 100.

In an implementation, with reference to FIG. 1a, along the first direction or the second direction, the overall rib face efficiency of at least part of the heat dissipation fins 120 in at least one end region is less than the overall rib face efficiency of at least part of the heat dissipation fins 120 located in a middle region.

Exemplarily, when a heat dissipation fin has a rib shape, the overall rib face efficiency satisfies η₀=(Aᵣ+η_{f}A_{f})/(Aᵣ+A_{f}), where Aᵣ is the surface area of a root between two ribs, A_{f} is the surface area of a rib, and η_{f} is the rib efficiency. The rib efficiency is the physical quantity that characterizes an effective degree of heat dissipation of the rib, which refers to the ratio of an actual amount of heat dissipation to a theoretical amount of heat dissipation (assuming that the temperature of the entire rib surface is equal to the rib base temperature). In a case where other parameters are unchanged, for any one rib, as the height of the rib increases, the rib efficiency decreases, the overall rib face efficiency increases, the heat dissipation surface area of this rib also increases, and the amount of heat dissipation of the rib will also increase accordingly.

In an implementation, with reference to FIG. 1a, along the first direction or the second direction, the height of at least part of the heat dissipation fins 120 in at least one end region is less than the height of at least part of the heat dissipation fins 120 located in a middle region.

Here, it should be noted that “the height of a heat dissipation fin 120” can be understood as the dimension of the heat dissipation fin 120 in a thickness direction of the base 110, that is, the dimension of the heat dissipation fin 120 in a direction perpendicular to the first direction and the second direction.

Exemplarily, the height of a part of the heat dissipation fins 120 in one of the end regions may be less than the height of a part of the heat dissipation fins 120 located in the middle region, and there can exist a heat dissipation fin 120 in the above one of the end regions with a height greater than or equal to the height of the heat dissipation fins 120 located in the middle region. Alternatively, the height of all the heat dissipation fins 120 in one of the end regions may be less than the height of the heat dissipation fins 120 located in the middle region. Still alternatively, the height of a part of the heat dissipation fins 120 in either end region may be less than the height of the part of the heat dissipation fins 120 located in the middle region, and there can exist a heat dissipation fin 120 in either end region with a height greater than or equal to the height of the heat dissipation fins 120 located in the middle region. Yet alternatively, the height of all the heat dissipation fins 120 in both end regions may be less than the height of the heat dissipation fins 120 located in the middle region.

Thus, when air flows through a heat dissipation channel 130, a contact area between side walls of heat dissipation fins 120 in an end region and the air is small, such that a heat exchange area is small, which satisfies a relatively low heat dissipation requirement of a heat generation component 211 opposite to the heat dissipation fins 120 in the end region; meanwhile, a contact area between side walls of heat dissipation fins 120 in the middle region and the air is large, such that a heat exchange area is large, which satisfies a relatively high heat dissipation requirement of a heat generation component 211 opposite to the heat dissipation fins 120 in the middle region, and can, in turn, effectively improves the heat dissipation effect of the heat sink 100.

In an implementation, the height of at least part of the heat dissipation fins 120 gradually decrease from the middle to the two ends along the first direction. An overall trend of the height of the plurality of heat dissipation fins 120 can gradually decrease from the middle to the two ends. At this time, the height of all the heat dissipation fins 120 may gradually decrease from the middle to the two ends. Alternatively, the height of a part of the plurality of heat dissipation fins 120 may gradually decrease from the middle to the two ends, and the height of the other part of the plurality of heat dissipation fins 120 does not gradually decrease from the middle to the two ends, for example, the height of the part of the heat dissipation fins 120 may not gradually decrease from the middle to the two ends due to assembly requirements such as a requirement to avoid certain components.

Thus, by enabling the height of at least part of the heat dissipation fins 120 to gradually decrease from the middle to the two ends, the heat dissipation capacity of at least the part of the heat dissipation fins 120 can gradually decrease from the middle to the two ends. On the one hand, the heat dissipation capacity of the heat dissipation fins 120 can be consistent with a heat dissipation requirement of corresponding heat dissipation fins 120, such that the heat dissipation of the heat sink 100 is more targeted; on the other hand, the heat dissipation fins 120 with a relatively low height incur the relatively low machining costs, occupy less space, and facilitate the space layout of the entire heat sink 100.

In an implementation, in conjunction with FIG. 1a, the plurality of heat dissipation fins 120 are divided into a plurality of second heat dissipation groups, wherein at least one second heat dissipation group includes a plurality of heat dissipation fins 120 equal in height, and the height of the heat dissipation fins 120 of the plurality of second heat dissipation groups gradually decreases from the middle to the two ends along the first direction.

For example, in the example of FIG. 1a, the plurality of heat dissipation fins 120 can be divided into three second heat dissipation groups, and the three second heat dissipation groups are a second heat dissipation group I, a second heat dissipation group II and a second heat dissipation group III arranged in sequence along the first direction, respectively. The second heat dissipation group II includes a plurality of heat dissipation fins 120 equal in height, and the second heat dissipation group I and the second heat dissipation group III respectively include a plurality of heat dissipation fins 120 with the height progressively increasing in sequence along a direction towards the second heat dissipation group II. At this time, along the first direction, the height of the heat dissipation fins 120 in the second heat dissipation group II is greater than the height of the heat dissipation fins 120 in the second heat dissipation group I, and the height of the heat dissipation fins 120 in the second heat dissipation group II is greater than the height of the heat dissipation fins 120 in the second heat dissipation group III.

Thus, with the above arrangement, the plurality of second heat dissipation groups can perform heat dissipation according to heat dissipation requirements of different regions on the circuit board 210, and since the plurality of heat dissipation fins 120 in the at least one second heat dissipation group are equal in height, the versatility of the plurality of heat dissipation fins 120 in the above at least one second heat dissipation group can be improved, thereby reducing the machining difficulty of the heat sink 100 and improving the production efficiency of the heat sink 100.

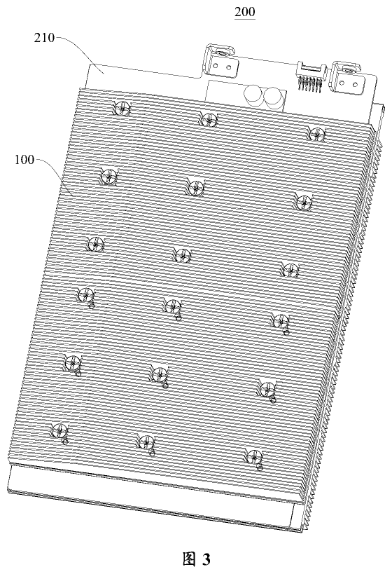

In an implementation, as shown in FIG. 2, along the first direction or the second direction, the width of at least part of the heat dissipation channels 130 in at least one end region is greater than the width of at least part of the heat dissipation channels 130 in a middle region. That is to say, along the first direction or the second direction, a density of at least part of the heat dissipation fins 120 in at least one end region is less than a density of at least part of the heat dissipation fins 120 located in a middle region.

Exemplarily, the width of a part of the heat dissipation channels 130 in one of the end regions may be greater than the width of a part of the heat dissipation channels 130 located in the middle region, and there can exist a heat dissipation fin 120 in the above one of the end regions with a width less than or equal to the width of the heat dissipation channels 130 located in the middle region. Alternatively, the width of all the heat dissipation channels 130 in the one of the end regions may be greater than the width of the heat dissipation channels 130 located in the middle region. Still alternatively, the width of a part of the heat dissipation channels 130 in either end region may be greater than the width of the part of the heat dissipation channel 130 located in the middle region, and there can exist a heat dissipation fin 120 in either end region with a width less than or equal to the width of the heat dissipation channels 130 located in the middle region. Yet alternatively, the width of all the heat dissipation channels 130 in both end regions may be also greater than the width of the heat dissipation channels 130 located in the middle region.

With such an arrangement, in a case where the heat sink 100 is used to perform heat dissipation for the circuit board 210, the number of heat dissipation fins 120 in the two end regions opposite to the circuit board 210 is small, such that a total heat exchange area of the heat dissipation fins 120 in the two end regions is small and the heat dissipation capacity is small, which can satisfy a relatively low heat dissipation requirement of heat generation components 211 opposite to the heat dissipation fins 120 in the two end regions, and can reduce a material cost of the heat dissipation fins 120 in the two end regions. Moreover, the number of heat dissipation fins 120 in the middle region opposite to the circuit board 210 is large, such that a total heat exchange area of the heat dissipation fins 120 in the middle region is large and the heat dissipation capacity is large, which can satisfy a relatively high heat dissipation requirement of heat generation components 211 in the middle region opposite to the heat dissipation fins 120, effectively reduce the temperature of the heat generation components 211, and ensure the heat dissipation effect of the heat sink 100.

In an implementation, the width of at least part of the heat dissipation channels 130 gradually increases from the middle to the two ends along the first direction. An overall trend of the width of the plurality of heat dissipation channels 130 can gradually increase from the middle to the two ends. At this time, the width of all the heat dissipation channels 130 may gradually increase from the middle to the two ends. Alternatively, the width of a part of the plurality of heat dissipation channels 130 may gradually increase from the middle to the two ends, and the width of the other part of the plurality of heat dissipation channels 130 does not gradually increase from the middle to the two ends, for example, the width of the above other part of the heat dissipation channels 130 may not gradually increase from the middle to the two ends due to assembly requirements such as a requirement to mount certain parts and components in the heat dissipation channels 130 and other factors.

Thus, by enabling the width of at least part of the heat dissipation channels 130 to gradually increase from the middle to the two ends, the heat dissipation capacity of at least part of the heat dissipation fins 120 can gradually decrease from the middle to the two ends. On the one hand, the heat dissipation capacity of the heat dissipation fins 120 can be consistent with a heat dissipation requirement of corresponding heat dissipation fins 120, such that the heat dissipation of the heat sink 100 is more targeted; on the other hand, heat dissipation fins 120 in a region where the width of heat dissipation channels 130a is relatively large are arranged in a more convenient manner, thereby making it convenient to machine the heat sink 100, and the heat dissipation channels 130 with the large width can avoid interference with other parts and components and play an effective avoidance effect.

In an implementation, as shown in FIG. 2, the plurality of heat dissipation fins 120 are divided into a plurality of third heat dissipation groups, wherein at least one third heat dissipation group defines a plurality of heat dissipation channels 130 equal in width, and the width of heat dissipation channels 130 of the plurality of third heat dissipation groups gradually increases from the middle to the two ends along the first direction.

Exemplarily, in conjunction with FIG. 2, the plurality of heat dissipation fins 120 can be divided into three third heat dissipation groups, and the three third heat dissipation groups are a third heat dissipation group I, a third heat dissipation group II and a third heat dissipation group III arranged in sequence along the first direction, respectively. A plurality of heat dissipation fins 120 in the third heat dissipation group II define a plurality of heat dissipation channels 130 equal in width, and a plurality of heat dissipation fins 120 in the third heat dissipation group I and the third heat dissipation group III respectively define a plurality of heat dissipation channels 130 with a width progressively decreasing in sequence along a direction towards the third heat dissipation group II. At this time, along the first direction, the width of the heat dissipation channels 130 defined by the heat dissipation fins 120 in the third heat dissipation group II is less than the width of the heat dissipation channels 130 defined by the heat dissipation fins 120 in the third heat dissipation group I, and the width of the heat dissipation channels 130 defined by the heat dissipation fins 120 in the third heat dissipation group II is less than the width of the heat dissipation channels 130 defined by the heat dissipation fins 120 in the third heat dissipation group III.

As such, the plurality of third heat dissipation groups can perform heat dissipation according to heat dissipation requirements of different regions on the circuit board 210, and since the at least one third heat dissipation group defines the plurality of heat dissipation channels 130 equal in width, the heat dissipation uniformity of heat generation components 211 opposite to the above at least one third heat dissipation group can be improved, such that temperatures of the heat generation components 211 can be more uniform.

In an implementation, along the first direction or the second direction, the surface area of at least part of the heat dissipation fins 120 in at least one end region can be less than the surface area of at least part of the heat dissipation fins 120 located in a middle region. That is to say, a product of a length (i.e., the dimension in the second direction), a thickness (i.e., the dimension in the first direction), and the height of at least part of the heat dissipation fins 120 in at least one end region is less than a product of a length, a thickness, and a height of at least part of the heat dissipation fins 120 located in a middle region.

As such, in a case where the heat sink 100 is used to perform heat dissipation for the circuit board 210, a heat dissipation area of heat dissipation fins 120 in the two end regions opposite to the circuit board 210 is small, and the heat dissipation capacity is small, which thereby can satisfy a relatively low heat dissipation requirement of heat generation components 211 opposite to the heat dissipation fins 120 in the two end regions, and reduce a material cost of the heat dissipation fins 120 in the two end regions. Moreover, a heat dissipation area of heat dissipation fins 120 in the middle region opposite to the circuit board 210 is large, and the heat dissipation capacity is large, which thereby can satisfy a relatively high heat dissipation requirement of heat generation components 211 in the middle region opposite to the heat dissipation fins 120, also effectively reduce the temperature of the heat generation components 211, and ensure the heat dissipation effect of the heat sink 100.

In an implementation, the surface area of at least part of the heat dissipation fins 120 gradually decreases from the middle to the two ends along the first direction. An overall trend of the surface area of the plurality of heat dissipation fins 120 can gradually decrease from the middle to the two ends. At this time, the surface area of all the heat dissipation fins 120 may gradually decrease from the middle to the two ends. Alternatively, the surface area of a part of the plurality of heat dissipation fins 120 may gradually decrease from the middle to the two ends, and the surface area of the other part of the plurality of heat dissipation fins 120 may not gradually decrease from the middle to the two ends, for example, the surface area of the above other part of the heat dissipation fins 120 may not gradually decrease from the middle to the two ends due to factors such as machining errors or assembly requirements.

Thus, by enabling the surface area of at least part of the heat dissipation fins 120 to gradually decrease from the middle to the two ends, the heat dissipation capacity of at least the part of the heat dissipation fin 120 can gradually decrease from the middle to the two ends, which can further ensure that the heat dissipation capacity of the heat dissipation fins 120 can be consistent with a heat dissipation requirement of corresponding heat dissipation fins 120, such that the heat dissipation of the heat sink 100 is more targeted. Moreover, the heat dissipation fins 120 with a relatively small surface area need fewer materials, which can reduce the cost of the entire heat sink 100.

In an implementation, the plurality of heat dissipation fins 120 are divided into a plurality of fourth heat dissipation groups, wherein at least one fourth heat dissipation group includes a plurality of heat dissipation fins 120 equal in surface area, and the surface area of the heat dissipation fins 120 of the plurality of fourth heat dissipation groups gradually decreases from the middle to the two ends along the first direction.

Exemplarily, the plurality of heat dissipation fins 120 can be divided into three fourth heat dissipation groups, and the three fourth heat dissipation groups are a fourth heat dissipation group I, a fourth heat dissipation group II and a fourth heat dissipation group III arranged in sequence along the first direction, respectively. A portion of the three fourth heat dissipation groups includes a plurality of heat dissipation fins 120 equal in surface area, and a plurality of heat dissipation fins 120 of the other part of the three fourth heat dissipation groups can progressively increase or decrease in sequence along the first direction, which can progressively increase or decrease in sequence from the middle to the two ends, or without any distribution rule, as long as it is ensured that the surface area of heat dissipation fins 120 in the fourth heat dissipation group I and the fourth heat dissipation group III is less than the surface area of heat dissipation fins 120 in the fourth heat dissipation group II. Certainly, it is also possible that each fourth heat dissipation group includes a plurality of heat dissipation fins 120 equal in surface area. The present application makes no limitation in this regard.

With such an arrangement, the plurality of fourth heat dissipation groups can perform heat dissipation according to heat dissipation requirements of different regions on the circuit board 210, and since the at least one fourth heat dissipation group includes the plurality of heat dissipation fins 120 equal in surface area, on the one hand, the heat dissipation uniformity of heat generation components 211 opposite to the at least one fourth heat dissipation group can be improved, such that temperatures of the heat generation components 211 can be more uniform; on the other hand, the mounting difficulty of the plurality of heat dissipation fins 120 in the above at least one fourth heat dissipation group can be reduced, and the mounting efficiency can be improved.

In an implementation, along the first direction or the second direction, the thermal conductivity of at least part of the heat dissipation fins 120 in at least one end region is less than the thermal conductivity of at least part of the heat dissipation fins 120 located in the middle region.

Exemplarily, the thermal conductivity of a part of the heat dissipation fins 120 in one of the end regions may be less than the thermal conductivity of a part of the heat dissipation fin 120 located in the middle region, and there can exist a heat dissipation fin 120 in the above one of the end regions with a thermal conductivity greater than or equal to the thermal conductivity of the heat dissipation fins 120 located in the middle region. Alternatively, the thermal conductivity of all the heat dissipation fins 120 in the one of the end regions may be less than the thermal conductivity of the heat dissipation fins 120 located in the middle region. Still alternatively, the thermal conductivity of a part of the heat dissipation fins 120 in either end region may be also less than the thermal conductivity of the part of the heat dissipation fins 120 located in the middle region, and there can exist a heat dissipation fin 120 in either end region with a thermal conductivity greater than or equal to the thermal conductivity of the heat dissipation fins 120 located in the middle region. Yet alternatively, the thermal conductivity of all the heat dissipation fins 120 in both end regions may be also less than the thermal conductivity of the heat dissipation fins 120 located in the middle region.

For example, the thermal conductivity of at least part of the heat dissipation fins 120 can gradually decrease from the middle to the two ends along the first direction. For example, the thermal conductivity of all the heat dissipation fins 120 may gradually decrease from the middle to the two ends. Alternatively, the thermal conductivity of a part of the plurality of heat dissipation fins 120 may gradually decrease from the middle to the two ends, and the thermal conductivity of the other part of the plurality of heat dissipation fins 120 may not gradually decrease from the middle to the two ends.

Thus, with the above arrangement, in a case where the heat sink 100 is used to perform heat dissipation for the circuit board 210, the heat dissipation fins 120 in the two end regions opposite to the circuit board 210 can be machined by adopting a material with a small thermal conductivity, such that a thermal resistivity of the heat dissipation fins 120 in the two end regions is relatively high, and the heat dissipation capacity is low, which can satisfy a relatively low heat dissipation requirements of heat generation components 211 opposite to the heat dissipation fins 120 in the two end regions, and can reduce the cost of the heat dissipation fins 120 in the two end regions. Moreover, the heat dissipation fins 120 in the middle region opposite to the circuit board 210 can be machined by adopting a material with a large thermal conductivity, such that a thermal resistivity of the heat dissipation fins 120 in the middle region is relatively low, and the heat dissipation capacity is high, which can satisfy a relatively high heat dissipation requirement of heat generation components 211 opposite to the heat dissipation fins 120 in the middle region, thereby avoiding damages to the heat generation components 211 due to a too high temperature and ensuring the normal operation of the heat generation components 211.

In an implementation, as shown in FIG. 7, along the first direction or the second direction, the height of at least one end of at least one of the heat dissipation fins 120 is less than the height of a middle portion of the heat dissipation fin 120. For example, in the example of FIG. 7, the height of one end of each of the heat dissipation fins 120 is less than the height of a middle portion of the heat dissipation fin 120, and the height of the other end of the heat dissipation fin 120 is equal to the height of the middle portion of the heat dissipation fin 120.

With such an arrangement, the height of at least one end of each heat dissipation fin 120 is small, and the occupied space is small, which, when the heat sink 100 is applied to the electronic device 200, can effectively avoid structures on the shell of the electronic device 200, thereby facilitating the layout of the structures on the shell.

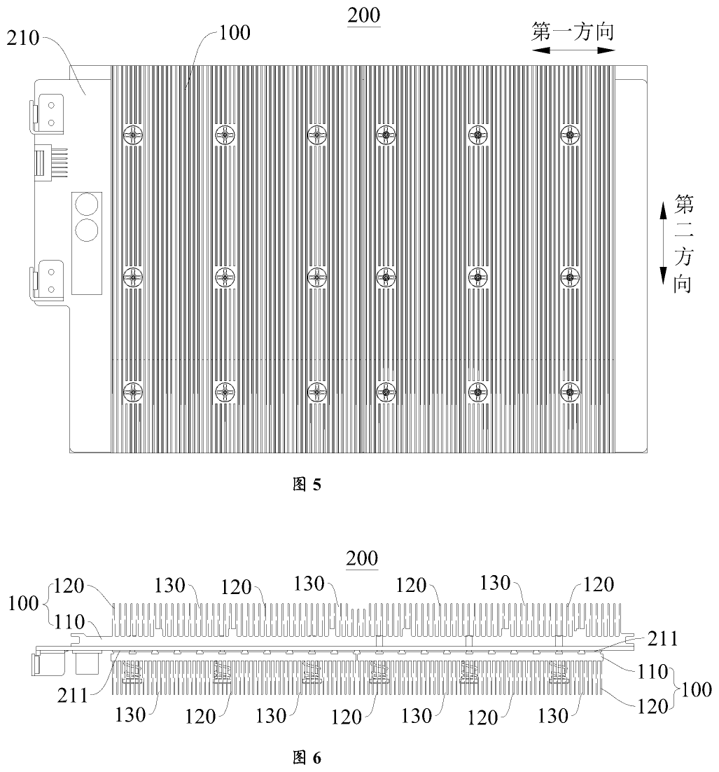

As shown in FIG. 3 to FIG. 7, an electronic device 200 according to an embodiment of the second aspect of the present application includes a circuit board 210 and a plurality of heat sinks 100. Optionally, the electronic device 200 can be a computing device, for example, but not limited to, a mining machine.

A first side of the circuit board 210 is provided with a plurality of heat generation components 211. For example, in the example of FIG. 4, the heat generation components 211 can be a plurality of chips arranged in an array. Certainly, the heat generation components 211 can also be other structures on the circuit board 210, such as a capacitor, a resistor, and the like.

The heat sinks 100 are a heat sink 100 according to any one implementation of the above first aspect of the present application, wherein the heat sinks 100 are disposed on the first side or a second side of the circuit board 210, and a base 110 of at least part of the heat sinks 100 can be in contact with corresponding heat generation components 211.

According to the electronic device 200 of the embodiment of the present application, by adopting the above heat sinks 100, heat dissipation can be performed according to heat dissipation requirements of different regions on the circuit board 210, such that temperatures of the plurality of heat generation components 211 on the circuit board 210 are more uniform, the service life of the plurality of heat generation components 211 is prolonged, and the cost of the electronic device 200 can be reduced.

In an implementation, the plurality of heat sinks 100 include a first heat sink and a second heat sink disposed on the first side and the second side of the circuit board 210, respectively, wherein the base 110 of the first heat sink is in contact with the corresponding heat generation component(s) 211.

Exemplarily, when the plurality of heat generation components 211 are in operation, a part of heat generated by the heat generation components 211 can be directly conducted to the base 110 of the first heat sink, and then conducted to a plurality of heat dissipation fins 120 of the first heat sink through the base 110 of the first heat sink. When air flows through heat dissipation channels 130 defined by the plurality of heat dissipation fins 120 of the first heat sink, heat on the base 110 and the heat dissipation fins 120 of the first heat sink can be taken away, achieving dissipation of the heat.

The base 110 of the second heat sink can be in contact with a second side surface of the circuit board 210. The other part of the heat generated by the heat generation components 211 can be conducted to the base 110 of the second heat sink through the circuit board 210, and then conducted to a plurality of heat dissipation fins 120 of the second heat sink through the base 110 of the second heat sink. When air flows through heat dissipation channels 130 defined by the plurality of heat dissipation fins 120 of the second heat sink, heat on the base 110 and the heat dissipation fins 120 of the second heat sink can be taken away, thereby achieving effective heat dissipation for the heat generation components 211.

In an optional implementation, at least one heat conducting member is disposed between the circuit board 210 and the heat sinks 100.

Exemplarily, at least part of the heat conducting member can be provided between the base 110 of the first heat sink and the heat generation components 211. For example, the circuit board 210 can include component parts and mounting parts, wherein the plurality of heat generation components 211 are provided on the component parts, and fasteners can pass through the base 110 of the heat sink to connect to the mounting parts, thereby fixing the heat sinks on the circuit board 210. An insulating layer is disposed on the first heat sink, and exemplarily, an insulating layer may be disposed on at least one of the base 110 and the heat dissipation fins 120. For example, an insulating layer can be disposed on a side surface of the base 110 of the first heat sink towards the circuit board 210 to achieve insulation.

Optionally, the heat conducting member can be a silicone grease strip, and there can be a plurality of silicone grease strips. For example, in the example of FIG. 4, six rows and twenty-two columns of the heat generation components 211 are provided on the circuit board 210. The silicone grease strips can extend along the first direction, and one strip-shaped silicone grease strip can be pasted on each row of the heat generation components 211. At this time, there can be six silicone grease strips. Alternatively, a plurality of silicone grease strips disposed at intervals can be pasted on each row of the heat generation components 211. The silicone grease strips can also extend along the second direction. At this time, one strip-shaped silicone grease strip can be pasted on each column of the heat generation components 211, and at this time, there can be twenty-two silicone grease strips. Alternatively, a plurality of silicone grease strips disposed at intervals are pasted on each column of the heat generation components 211. Certainly, the silicone grease strips may not correspond to the rows or columns of the heat generation components 211 one by one.

Thus, with such an arrangement, the heat conducting member can enhance the heat conducting effect between the heat generation components 211 and the base 110 of the first heat sink, such that heat generated during the operation of the heat generation component 211 can be better conducted to the first heat sink, such that the first heat sink can effectively discharge the heat of the heat generation components 211, effectively reduce the temperature of the heat generation components 211, and prolong the service life of the heat generation components 211.

It should be noted that, in the above implementations, an explanation is made by taking an example in which all the heat conducting members are provided between the base 110 of the first heat sink and the heat generation components 211. It can be understood that the heat conducting members can also be all located between two adjacent rows of the heat generation components 211 (i.e., in the mounting parts of the circuit board 210). Alternatively, a part of the plurality of heat conducting members are provided between the base 110 of the first heat sink and the heat generation components 211, and the other part of the plurality of heat conducting members are provided between the base 110 of the heat sink 100 and the mounting parts of the circuit board 210. The presents application makes no limitation in this regard.

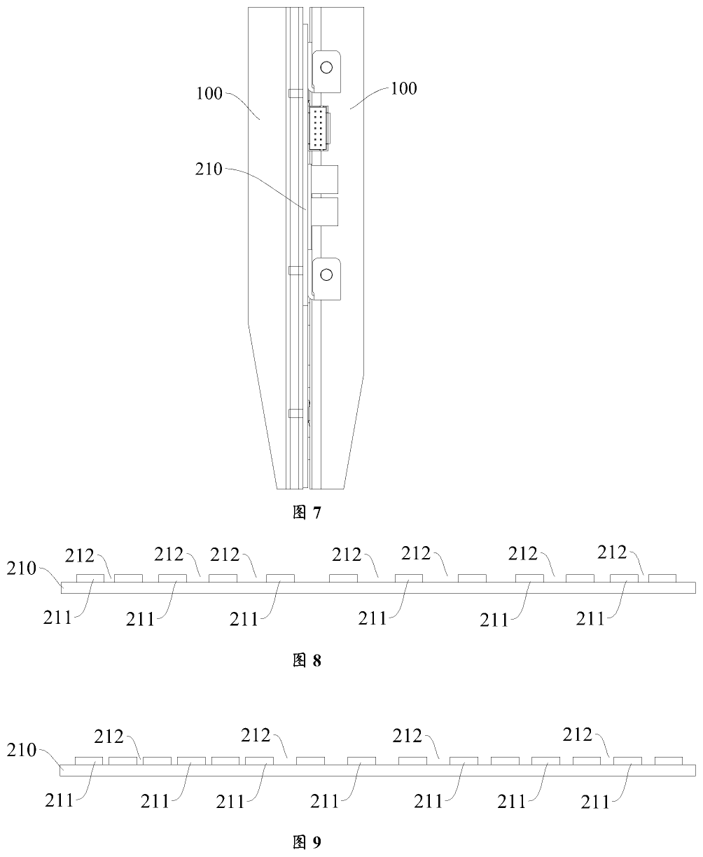

In an implementation, as shown in FIG. 8 and FIG. 9, the plurality of heat generation components 211 are disposed at intervals along the first direction to define a plurality of heat dissipation gaps 212, and the circuit board 210 is adapted to be placed in heat dissipation channels such as the heat dissipation channels 130, wherein the first direction is a direction perpendicular to an extending direction of the heat dissipation channels. Along the first direction or the second direction, the dimension of at least part of the heat dissipation gaps 212 in at least one end region is less than the dimension of at least part of the heat dissipation gaps 212 in a middle region.

The “middle region” refers to a region located between two end regions of the circuit board 210, and is not limited to a region located at the center of the circuit board 210. One end region or two end regions of the circuit board 210 refer to a region located at an end portion of the circuit board 210 along the first direction or the second direction. No limitation is made in this embodiment on a range or size of the one end region, the two end regions, or the middle region.

Exemplarily, the dimension of a part of the heat dissipation gaps 212 in one of the end regions may be less than the dimension of a part of the heat dissipation gaps 212 located in the middle region, and there can exist a heat dissipation gap 212 with a dimension greater than or equal to the dimension of the heat dissipation gaps in the middle region. Alternatively, the dimension of all the heat dissipation gaps 212 in one of the end regions may be less than the dimension of the heat dissipation gaps 212 located in the middle region. Still alternatively, the dimension of a part of the heat dissipation gap 212 in either end region may be also less than the dimension of the portion of the heat dissipation gaps 212 located in the middle region, and there can exist a heat dissipation gap 212 in either end region with a dimension greater than or equal to the dimension located in the middle region. Yet alternatively, it is also possible that the dimension of all the heat dissipation gaps 212 in both end regions is less than the dimension of the heat dissipation gaps 212 located in the middle region.

Thus, the dimension of the heat dissipation gaps 212 located in the middle region in the first direction or the second direction is relatively large, and heat generation components 211 in the middle region are arranged in a relatively sparse manner, such that heat generated by the heat generation components 211 in the middle region is relatively small, and there are larger heat dissipation gaps, such that the heat can be effectively dissipated. Due to a close distance between the two end regions and the outside, there is large heat dissipation space. By enabling heat generation components 211 in the two end regions to be arranged in a relatively dense manner, space on the circuit board 210 can be fully utilized while it is ensured that the heat generation components 211 can effectively dissipate heat, which increases the number of the heat generation components 211; and in a case where the electronic device 200 is a computing device, the computing capacity of the computing device can be effectively enhanced.

In an implementation, with reference to FIG. 8, the dimension of at least part of the heat dissipation gaps 212 gradually decreases from the middle to the two ends along the first direction. An overall trend of the dimension of the plurality of heat dissipation gaps 212 can gradually decrease from the middle to the two ends. At this time, the dimension of all the heat dissipation gaps 212 may gradually decrease from the middle to the two ends. Alternatively, the dimension of a part of the plurality of heat dissipation gaps 212 may gradually decrease from the middle to the two ends, and the dimension of the other part of the plurality of heat dissipation gaps 212 does not gradually decrease from the middle to the two ends, for example, the dimension of the other part of the heat dissipation gap 212 may not gradually decrease from the middle to the two ends due to mounting requirements, such as a requirement to avoid some parts and components.

Thus, a distance between a region where the plurality of heat generation components 211 are and the outside gradually decreases from the middle to the two ends along the first direction, and the efficiency of heat exchange with the outside accordingly gradually increases from the middle to the two ends. By enabling the dimension of at least part of the heat dissipation gaps 212 to gradually decrease from the middle to the two ends, a density of at least the part of the heat generation components 211 is negatively correlated with a distance between a region where they are and the outside, thereby effectively increasing the total number of the heat generation components 211 while effectively enhancing the heat dissipation effect of the heat generation components 211, which, in turn, enhances the computing capacity of the electronic device 200.

In an implementation, as shown in FIG. 9, the plurality of heat dissipation gaps 212 can be divided into a plurality of gap groups, wherein at least one gap group includes a plurality of heat dissipation gaps 212 equal in dimension, and the dimension of the heat dissipation gaps 212 of the plurality of gap groups gradually decreases from the middle to the two ends along the first direction.

For example, the plurality of heat dissipation gaps 212 can be divided into three gap groups, each including a plurality of heat dissipation gaps 212 equal in dimension, and the three gap groups are a first gap group, a second gap group and a third gap group arranged in sequence along the first direction. At this time, along the first direction, the dimension of the heat dissipation gaps 212 in the second gap group is greater than the dimension of the heat dissipation gaps 212 in the first gap group, and the dimension of the heat dissipation gaps 212 in the second gap group is greater than the dimension of the heat dissipation gaps 212 in the third gap group.

Thus, corresponding heat dissipation gaps 212 can be disposed according to a distance between heat generation components 211 in different regions on the circuit board 210 and the outside, and since at least one gap group includes a plurality of heat dissipation gaps 212 equal in dimension, the production efficiency of the circuit board 210 can be effectively enhanced.

In an implementation, the electronic device 200 further includes a shell, wherein an accommodating cavity is defined in the shell, the circuit board 210 and the plurality of heat sinks 100 are located in the accommodating cavity, a guide strip is provided on one of the shell and the heat sinks 100, a guide slot 140 is formed on the other of the shell and the heat sinks 100, and the guide strip is movably fitted in the guide slot 140. That is to say, it is possible to provide a guide strip on the shell, and form a guide slot 140 on the heat sinks 100. Alternatively, it is also possible to provide a guide strip on the heat sink 100, and form a guide slot 140 on the shell.

Exemplarily, the shell can be substantially in a rectangular parallelepiped structure, and the shell includes two first side faces opposite to each other and two second side faces opposite to each other, wherein the circuit board 210 is parallel to the first side faces and perpendicular to the second side faces. A fan can be disposed at each second side face, so as to enable outside air to enter into the shell under the action of the fan, flow through the heat dissipation channels 130 of each heat sink 100, and then discharge heat generated by the heat generation components 211.

Thus, the cooperation between the guide strip and the guide slot 140 can play an effective guiding effect, and during mounting, the circuit board 210 and the heat sinks 100 can be mounted into the accommodating cavity through the cooperation between the guide strip and the guide slot 140, which can improve the mounting efficiency. Moreover, the cooperation between the guide strip and the guide slot 140 can also play an effective limiting effect, avoiding the circuit board 210 and the heat sinks 100 from be displaced in the accommodating cavity, and improving the structural stability of the entire electronic device 200.

Other constructions of the heat sink and the electronic device 200 in the above embodiments can be adopted in various technical solutions known to those of ordinary skill in the art now and in the future, and will not be described in detail herein.

A circuit board 210 according to an embodiment of the third aspect of the present application includes a substrate and a plurality of heat generation components 211, wherein the plurality of heat generation components 211 can be disposed on a first side of the substrate.

In the description of this specification, it should be understood that the terms “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential” and the like indicate orientations or positional relationships based on the orientations or positional relationships shown in the drawings, and are only for the convenience of describing the present application and simplifying the description, and do not indicate or imply that a device or element as mentioned must have a particular orientation, or be constructed and operated in a particular orientation, and therefore should not be understood as a limitation on the present application.

In addition, the terms “first” and “second” are used for descriptive purposes only and should not be understood as indicating or implying relative importance or implicitly stating the number of technical features as indicated. Accordingly, a feature defined by “first” or “second” may explicitly or implicitly include one or more of the features.

In the present application, unless otherwise clearly specified and defined, the terms “mount”, “connect with”, “connect”, “fix” and the like should be understood in a broad sense. For example, it is possible to be a fixed connection, a detachable connection, or an integration; it is possible to be a mechanical connection, an electrical connection, or a communication; it is possible to be a direct connection, or an indirect connection through an intermediate medium, or an internal communication between two elements or an interaction relationship between two elements. For those skilled in the art, the specific meanings of the above terms in the present application can be understood as a specific case may be.

In the present application, unless otherwise clearly specified and defined, a first feature being “on” or “under” a second feature may include a case that the first and second features are in direct contact, or a case that the first and second features are not in direct contact but are in contact through an additional feature between them. Moreover, a first feature being “on”, “above” and “over” a second feature includes a case that the first feature is directly above and obliquely above the second feature, or simply represents that the first feature is higher in level than the second feature. A first feature being “under”, “below” and “beneath” a second feature includes a case that the first feature is directly below and obliquely below the second feature, or simply represents that the first feature is lower in level than the second feature.

The disclosure above provides many different embodiments or instances to achieve the different structures of the present application. In order to simplify the disclosure of the present application, the parts and settings of particular instances are described above. Certainly, they are only examples, and their purpose is not to limit the present application. In addition, in the present application, reference numerals and/or reference letters can be repeated in different instances, and such repetition is for the purpose of simplification and clarity, which itself does not indicate the relationships between the various implementations and/or settings discussed.

Described above are only specific implementations of the present application, but the scope of protection of the present application is not limited thereto. Any technicians familiar with this technical field can readily envisage various changes or substitutions within the technical scope disclosed in the present application, all of which should be included in the scope of protection of the present application. Therefore, the scope of protection of the present application should be based on the scope of protection of the attached claims.

What is claimed is:

1. A heat sink, comprising:
a base; and
a plurality of heat dissipation fins disposed on the base at intervals along a first direction, wherein two of the heat dissipation fins adjacent to each other and the base jointly define a heat dissipation channel extending along a second direction perpendicular to the first direction.

2. The heat sink of claim 1, wherein, along the first direction or the second direction, the heat dissipation capacity of at least part of the heat dissipation fins in at least one end region is less than the heat dissipation capacity of at least part of the heat dissipation fins located in a middle region.

3. The heat sink of claim 1, wherein, along the first direction or the second direction, the overall rib face efficiency of at least part of the heat dissipation fins in at least one end region is less than the overall rib face efficiency of at least part of the heat dissipation fins located in a middle region.

4. The heat sink of claim 1, wherein, along the first direction or the second direction, the height of at least part of the heat dissipation fins in at least one end region is less than the height of at least part of the heat dissipation fins located in a middle region.

5. The heat sink of claim 1, wherein, along the first direction or the second direction, the width of at least part of the heat dissipation channels in at least one end region is greater than the width of at least part of the heat dissipation channels located in a middle region.

6. The heat sink of claim 1, wherein, along the first direction or the second direction, the surface area of at least part of the heat dissipation fins in at least one end region is less than the surface area of at least part of the heat dissipation fins located in a middle region.

7. The heat sink of claim 1, wherein, along the first direction or the second direction, the thermal conductivity of at least part of the heat dissipation fins in at least one end region is less than the thermal conductivity of at least part of the heat dissipation fins located in a middle region.

8. The heat sink of claim 1, wherein, along the first direction or the second direction, the height of at least one end of at least one of the heat dissipation fins is less than the height of a middle portion of the heat dissipation fin.

9. An electronic device, comprising:
a circuit board having a first side provided with a plurality of heat generation components; and
a plurality of heat sinks of claim 1, wherein the heat sinks are disposed on the first side or a second side of the circuit board.

10. The electronic device of claim 9, wherein the heat sinks comprise a first heat sink disposed on the first side, and a base of the first heat sink is at least partially in contact with the corresponding heat generation component(s).

11. The electronic device of claim 10, wherein an insulating layer is disposed on the first heat sink, and the insulating layer at least partially covers a surface of the first heat sink.

12. The electronic device of claim 9, wherein at least one heat conducting member is disposed between the circuit board and the heat sinks.

13. The electronic device of claim 9, wherein the plurality of heat generation components are disposed at intervals along the first direction to define a plurality of heat dissipation gaps, the circuit board is adapted to be placed in the heat dissipation channels, and, along the first direction or the second direction, the dimension of at least part of the heat dissipation gaps in at least one end region is less than the dimension of at least part of the heat dissipation gaps located in a middle region.

14. The electronic device of claim 9, further comprising: a shell, wherein an accommodating cavity is defined in the shell, the circuit board and the heat sinks are both located in the accommodating cavity, a guide strip is provided on one of the shell and the heat sinks, a guide slot is formed on the other of the shell and the heat sinks, and the guide strip is movably fitted in the guide slot.

15. A circuit board, comprising:
a substrate; and
a plurality of heat generation components disposed on a first side of the substrate, wherein the plurality of heat generation components is disposed at intervals along a first direction to define a plurality of heat dissipation gaps, the circuit board is adapted to be placed in heat dissipation channels, and the first direction is a direction perpendicular to an extending direction of the heat dissipation channels.

16. The circuit board of claim 15, wherein, along the first direction or the extending direction of the heat dissipation channel, the dimension of at least part of the heat dissipation gaps in at least one end region is less than the dimension of at least part of the heat dissipation gaps located in a middle region.
